(19) United States
(12) Patent Application Publication
(10) Pub. No.: US 2025/0336846 A1
(43) Pub. Date: Oct. 30, 2025

(54) TSV MOISTURE BARRIER

(71) Applicant: INTERNATIONAL BUSINESS MACHINES CORPORATION, ARMONK, NY (US)

(72) Inventors: Mukta Ghate Farooq, HOPEWELL JCT, NY (US); Jennifer Oakley, COHOES, NY (US); Jennifer Church, ALBANY, NY (US)

(21) Appl. No.: 18/648,444

(22) Filed: Apr. 28, 2024

(51) Int. Cl. H01L 23/00; H01L 21/768; H01L 23/48; H01L 23/522; H01L 23/528

(52) U.S. Cl. CPC H01L 23/564; H01L 21/76898; H01L 23/481; H01L 23/5226; H01L 23/5283

(57) ABSTRACT

A moisture barrier for a semiconductor structure includes a solid bar that is tapered from an uppermost portion to a lowermost portion and extends along a length of the moisture barrier to form a collar that surrounds a designated area of the semiconductor structure configured to arrange at least one through silicon via (TSV). A plurality of patterning assist lines are arranged at different vertical levels of tapering of the solid bar within a footprint having a width defined by a topmost level of the solid bar.

### BACKGROUND

### Technical Field

The present disclosure is generally related to semiconductors having Through Silicon Vias (TSVs), and more particularly, to moisture barriers arranged around TSVs.

### Description of the Related Art

Moisture barriers create protection for TSVs against moisture ingress that can cause loss of integrity of semiconductor structures. Typically, a crackstop-like moisture oxidation barrier prevents the moisture ingress into the back-end dielectrics when a TSV is etched in the high or late back end.

### SUMMARY

A moisture barrier for a semiconductor structure includes a solid bar that is tapered from an uppermost portion to a lowermost portion and extends along a length of the moisture barrier to form a collar that surrounds a designated area of the semiconductor structure configured to arrange at least one through silicon via (TSV). A plurality of patterning assist lines for wire pitches are arranged at different vertical levels of tapering of the solid bar within a footprint having a width defined by a topmost level of the solid bar.

### BRIEF DESCRIPTION OF THE DRAWINGS

The drawings are of illustrative embodiments. They do not illustrate all embodiments. Other embodiments may be used in addition to or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 is an illustration of a structure for a TSV moisture barrier, consistent with an illustrative embodiment.

FIG. 2A is a top view of TSV with surrounding thin wire fill, consistent with an illustrative embodiment.

FIG. 2B illustrates the voltage ramp of wafers with TSVs.

FIG. 2C illustrates the voltage ramp of wafers with TSVs and with a walled moisture oxidation barrier, consistent with an illustrative embodiment.

FIG. 3A illustrates a cross-sectional view from a top portion of the TSV and moisture barrier, consistent with an illustrative embodiment.

FIG. 3B illustrates a front view of the TSV and moisture barrier showing the cut for the top level cross-section, consistent with an illustrative embodiment.

FIG. 4A illustrates a cross-sectional view from a >100 nm pitch (P) level portion of the TSV and moisture barrier, consistent with an illustrated embodiment.

FIG. 4B illustrates a front view of the TSV and moisture barrier showing the cut for the ≤80P level cross-section, consistent with an illustrative embodiment.

FIG. 5A illustrates a cross-sectional view from a level with a pitch <100 nm or pitch ≥80 nm level portion of the TSV and moisture barrier, consistent with an illustrative embodiment.

FIG. 5B illustrates a front view of the TSV and moisture barrier showing the cut for a pitch <80 nm or pitch ≥30 nm level cross-section, consistent with an illustrative embodiment.

FIG. 6A illustrates a cross-sectional view of the TSV and moisture barrier at the <30 nm P level portion, consistent with an illustrative embodiment.

FIG. 6B is a front view of the TSV and moisture barrier showing the cut for a <30 nm P level cross-section, consistent with an illustrative embodiment.

FIG. 6C is a front view of the TSV and moisture barrier including a second TSV in the patterning assist lines area, and connections between pitch patterning assist lines of different pitches along different vertical levels, consistent with an illustrative embodiment.

FIG. 7 shows reference data and spacing of patterning assist lines, consistent with an illustrative embodiment.

FIG. 8 shows reference data and spacing of patterning assist lines, consistent with an illustrative embodiment.

FIG. 9 is a flowchart illustrating a method of constructing a semiconductor structure with a TSV and moisture barrier, consistent with lines, consistent with an illustrative embodiment.

### DETAILED DESCRIPTION

In the following detailed description, numerous specific details are set forth by way of examples to provide a thorough understanding of the relevant teachings. However, it is to be understood that the present teachings may be practiced without such details. In other instances, well-known methods, procedures, components, and/or circuitry have been described at a relatively high-level, without detail, to avoid unnecessarily obscuring aspects of the present teachings. It is also to be understood that the present disclosure is not limited to the depictions in the drawings, as there may be fewer elements or more elements than shown and described.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

### Technical Advantages and Support

It is to be understood that some of the advantages of the present disclosure are provided herein below. However, a person of ordinary skill in the art will appreciate that additional advantages may exist in addition to those described herein.

In an embodiment, a moisture barrier for a semiconductor structure includes a solid bar that is tapered from an uppermost portion to a lowermost portion and extends along a length of the moisture barrier to form a collar that surrounds a designated area of the semiconductor structure configured to arrange at least one through silicon via (TSV). A plurality of patterning assist lines for wire pitches are arranged at different vertical levels adjacent the solid bar within a footprint having a width defined by a topmost level of the solid bar. This structure increases available space on the semiconductor structure by eliminating a “device prohibit zone/keep out zone” that is used in conventional structures.

In an embodiment, which may be combined with the preceding embodiment, the solid bar is tapered so that the width of the topmost portion is the widest portion, and the patterning assist lines have different pitches at the different vertical levels.

In one embodiment, which can be combined with one or more preceding embodiments, the patterning assist lines have the same size pitch at a particular vertical level of the different vertical levels.

In one embodiment, which can be combined with one or more preceding embodiments, the at least one TSV is arranged in the designated area of the semiconductor device, and the moisture barrier extends at least along a Back End of Line (BEOL) of the semiconductor device.

In one embodiment, which can be combined with one or more preceding embodiments, the thickness of the patterning assist lines on a particular vertical level increases as the distance from the at least one TSV decreases.

In one embodiment, which can be combined with one or more preceding embodiments, the moisture barrier includes at least three different vertical levels within the footprint of the solid bar at which the patterning assist lines are arranged.

In one embodiment, which can be combined with one or more preceding embodiments, a first pitch of the patterning assist lines is largest at a topmost first vertical level of the three different vertical levels, a second pitch of the patterning assist lines at a second vertical level below the first vertical level is smaller than the first pitch, and a third pitch of the patterning assist lines at a third vertical level below the second vertical level is smallest.

In one embodiment, which can be combined with one or more preceding embodiments, the patterning assist lines of the first vertical level are connected to the patterning assist lines of the second vertical level.

In one embodiment, which can be combined with one or more preceding embodiments, the patterning assist lines of the second level are connected to the patterning assist lines of the third vertical level.

In one embodiment, which can be combined with one or more preceding embodiments, the patterning assist lines of the first vertical level are connected to the patterning lines of the second vertical level, and the patterning assist lines of the second vertical level are connected to the patterning assist lines of the third vertical level.

In one embodiment, which can be combined with one or more preceding embodiments, at least a second TSV is arranged between the different vertical levels of the patterning assist lines.

In an embodiment, a method of constructing a moisture barrier for a semiconductor structure includes arranging in a semiconductor structure a solid bar that is tapered from an uppermost portion to a lowermost portion and surrounds a designated area of the semiconductor structure configured to arrange at least one through silicon via (TSV). A plurality of patterning assist lines are arranged at different vertical levels adjacent the solid bar within a footprint of the solid bar having a width defined by a topmost level of the solid bar.

In one embodiment, which can be combined with the preceding embodiment, the patterning assist lines are provided with different pitches at the different vertical levels.

In one embodiment, which can be combined with one or more preceding embodiments, the patterning assist lines have the same size pitch at a particular vertical level of the different vertical levels.

In one embodiment, which can be combined with one or more preceding embodiments, the at least one TSV is arranged in the designated area of the semiconductor structure, and extending the moisture barrier at least along a Back End of Line (BEOL) of the semiconductor structure.

In one embodiment, which can be combined with one or more preceding embodiments, the thickness of the patterning assist lines on a particular vertical level is increased as the distance from the at least one TSV is decreased.

In one embodiment, which can be combined with one or more preceding embodiments, the patterning assist lines of at least three different vertical levels are arranged within the footprint of the solid bar.

In one embodiment, which can be combined with one or more preceding embodiments, the patterning assist lines are arranged so that a first pitch is largest at a topmost first vertical level of the three different vertical levels, a second pitch of the patterning assist lines at a second vertical level below the first vertical level is smaller than the first pitch, and a third pitch of the patterning assist lines at a third vertical level below the second vertical level is smallest.

In one embodiment, which can be combined with one or more preceding embodiments, the patterning assist lines of at least some of the at least three different vertical levels are connected.

In one embodiment, which can be combined with one or more preceding embodiments, at least a second TSV is provided. The second TSV is arranged between the different vertical levels of the patterning assist lines.

### Overview

The present disclosure is generally directed to a moisture barrier for semiconductor structures and a method of manufacture. According to the present disclosure, the moisture barrier creates a protection against moisture ingress at low k levels with fine pitch wire where moisture is most likely to cause a loss of integrity.

The moisture barrier of the present disclosure combines the benefits of a moisture barrier with patterning assist lines, eliminating the need for two distinct structures. The moisture barrier provides a structure that ensures patterning fidelity immediately next to the TSV, thereby reducing or even eliminating a prohibitive zone/keep-out zone that is used with known moisture barriers in semiconductor structures with TSVs. TSVs and their associated surrounding structures occupy valuable space on semiconductor structures that cannot be used for devices or wiring.

It is to be understood that although a single-walled structure is shown herein, the moisture barrier of the present disclosure can also be provided with a second wall (e.g., a double-walled structure). The double-walled feature serves two functions: moisture barrier and patterning assist. The patterning assist feature is novel when compared with conventional moisture barrier structures. The size of the double-walled feature is dictated by a minimum size and a spacing of the top level, where the patterning assist features have less of an effect on yield.

Conventional semiconductor structures having TSVs and moisture barriers typically were constructed with patterning assist features having a structure that was twice the width of the top level of the solid bar wall, plus the minimum space between those lines along with the minimum space to the TSV. However, the moisture barrier structure according to the present disclosure has a decrease in size to about one width of the top level plus the space to the TSV while keeping the patterning assist function at the lower level.

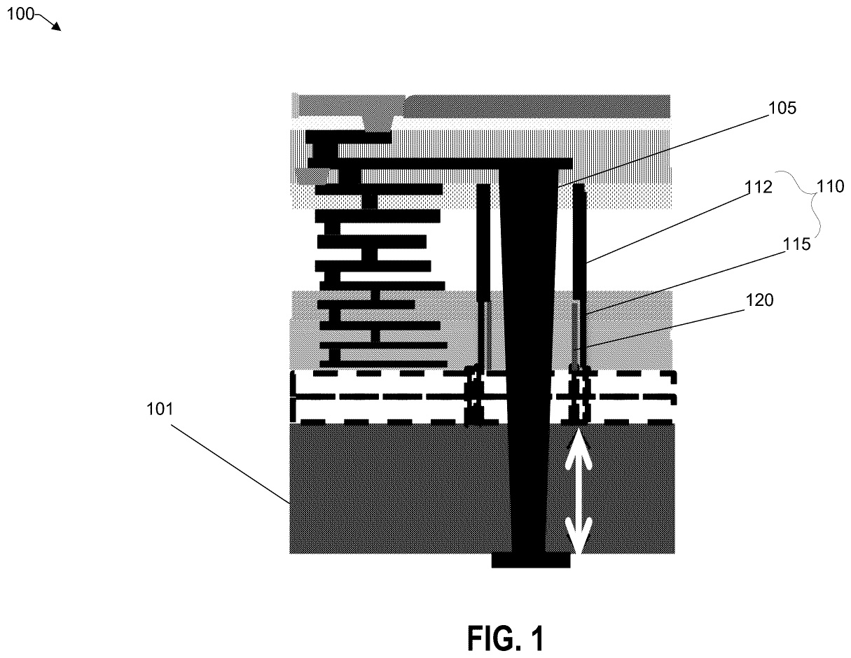

FIG. 1 is an illustration of a structure for a TSV moisture barrier, consistent with an illustrative embodiment. A semiconductor structure 100, includes a Silicon substrate 101, a vertical stack that includes wiring, and a crackstop-like moisture barrier when a TSV 105 is etched into the back end of the line. A single wall moisture barrier 110 is constructed of a solid bar 110 having a tapered portion 115 that tapers downward. Patterning assist lines 120 are arranged adjacent the TSV 105 within the footprint of the topmost wall of the solid bar 110 of the moisture barrier. In other words, the patterning assist lines 120 are arranged between the TSV and the tapered portion 115 of the solid bar 110.

It should be understood that the moisture barrier surrounds the TSV 105, and the view of FIG. 1 is a slice of the semiconductor structure. While a single-wall solid bar moisture barrier is shown, a double-wall solid bar moisture barrier may be used. In such a case, the double wall solid bar would have each have a tapered portion as the single wall shown in FIG. 1, and the pattering assist lines would be arranged within the footprint of the wider topmost position of the solid bar. One advantage of a double-walled structure that is arranged as the single-wall structure shown in FIG. 1 is that, if there is any gap or any other issue, and the first moisture barrier is actually penetrated, a second barrier would result in the integrity of the semiconductor structure being held. Thus, a second moisture barrier would completely prevent any moisture from entering the device's main part. However, the savings in space would not be as great. There can be other patterns of wiring using this TSV structure.

The real estate of the semiconductor structure being saved is the very expensive space in the back end of the line (BEOL). Further, there are savings in space and cost at the lower end of the BEOL.

According to an illustrative embodiment of the present disclosure, by using a single wall with the patterning assist lines arranged as described herein above, there is superior performance with regard to shorting, with little or no degradation as compared with conventional double-walled moisture barrier, and space savings on the semiconductor structure. For example, by arranging the patterning assist lines within the footprint of the moisture barrier, the need for a patterning chip-out zone beyond the boundary of the moisture barrier is eliminated.

According to an illustrative embodiment of the present disclosure, instead of having one, thick, solid patterning assist line at a given vertical level, a set of very narrow lines facilitates a wider patterning assist line for that given vertical level adjacent to the solid bar of the moisture barrier. Thus, the patterning assist lines appear as a type of a gradient arrangement. Such patterning structure ensures that the patterning assist lines in any given vertical level are robust, avoiding defects such as line flopover. In this gradient arrangement, there are transition spaces between the patterning assist lines which range from the very tight, from small lines to the largest line per level.

The area of the patterning assist lines remains inside the footprint of the topmost boundary of the solid bar of the moisture barrier. The moisture barrier as disclosed permits the arrangement of the patterning assist lines within the footprint of the moisture barrier, without having to dedicate an additional area of the semiconductor structure as in conventional structures.

In a conventional semiconductor structure with a TSV and a moisture barrier, care must be undertaken to make sure there are no signal lines or circuitry inside a keep-out zone. There is a creation of the creation of a “keep-out zone,” which is a forbidden zone for anything other than, some fill that is used for patterning and CMP uniformity.

### EXAMPLE EMBODIMENT(S)

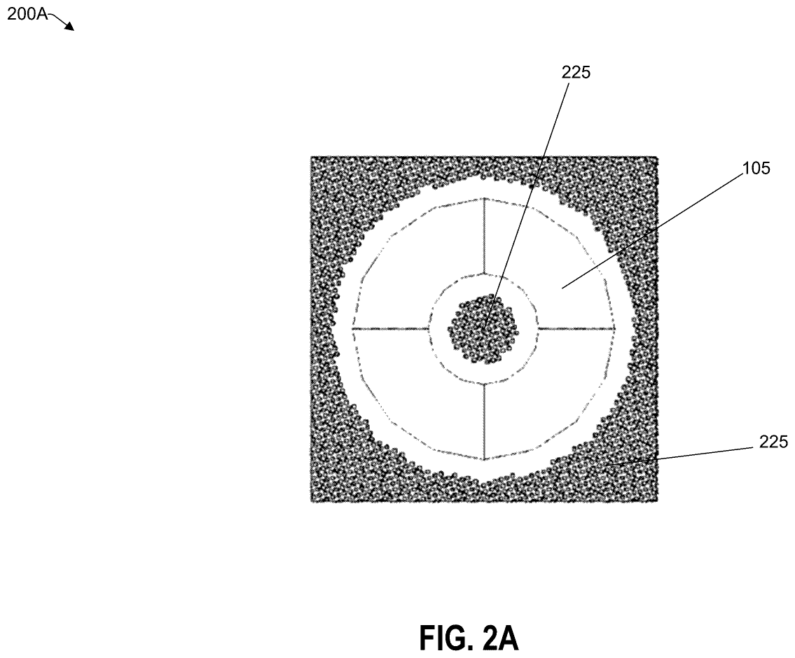

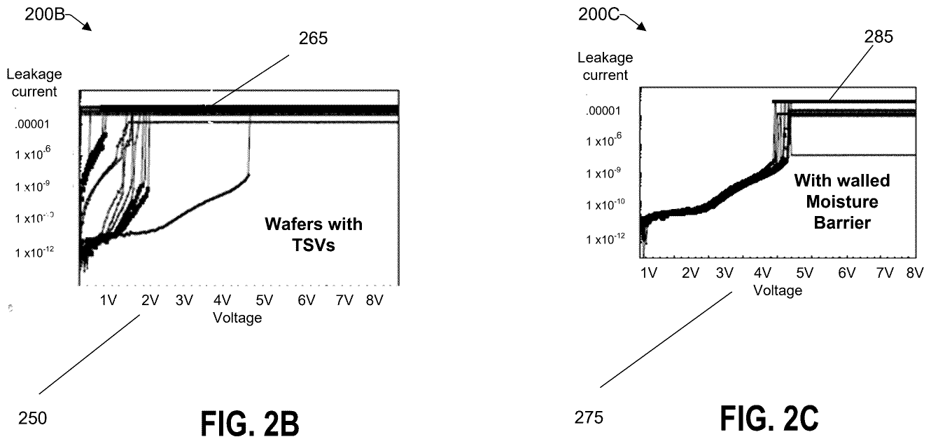

FIG. 2A is a top view 200A of TSV with surrounding thin wire fill, consistent with an illustrative embodiment. The TSV 105 when viewed from the top shows a thin-wire pattern 225 forming a collar that surrounds the TSV. The arrangement helps prevent moisture ingress from the TSV to other parts of the semiconductor structure.

FIG. 2B is a graph 200B illustrating the voltage ramp of wafers with TSVs. It is shown that with the use of TSVs for communication, at relatively low levels of voltage 250, there are shorts 265 for relatively small amounts of leakage current.

FIG. 2C is a graph 200C illustrating the voltage ramp of wafers with TSVs and with a walled moisture oxidation barrier, consistent with an illustrative embodiment. It is shown that with a walled moisture barrier (and a TSV) as in the structures disclosed herein, the voltage 275 at which shorts 285 occur is typically much higher (about 4V) versus about 1-1.5 V with a TSV, and without the moisture barrier (such shown in FIG. 2B).

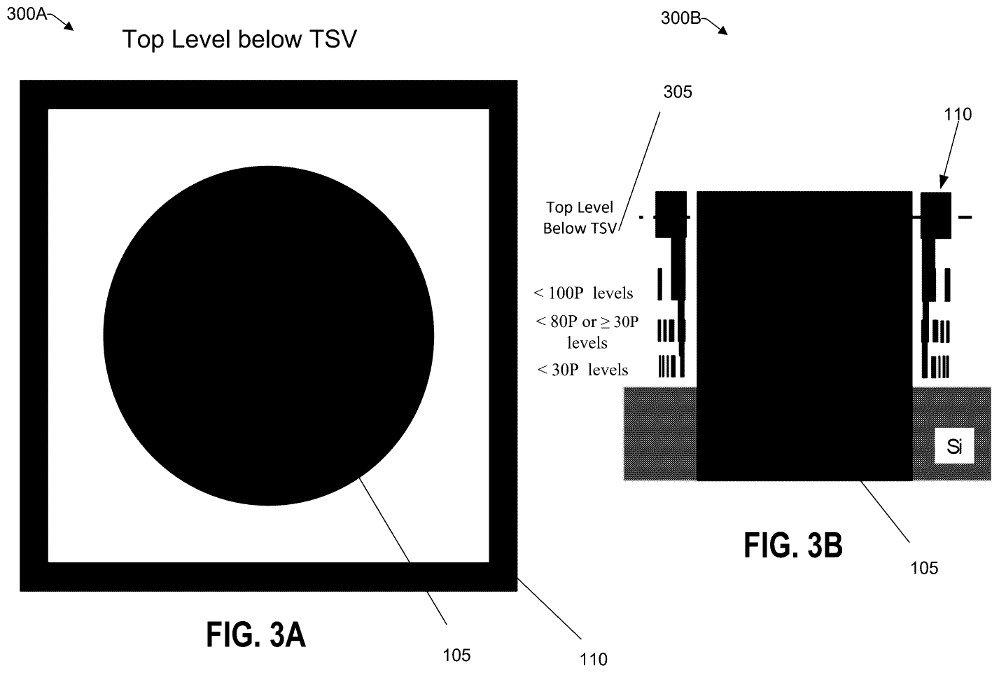

FIG. 3A illustrates a cross-sectional view 300A from a top portion of the TSV and moisture barrier, consistent with an illustrative embodiment. In FIG. 3A, due to the slice of the cross-section paying at the topmost portion of the solid bar moisture barrier 110, the TSC 105 and the solid bar surrounding the TSV 105 are visible. However, none of the patterning assist lines are visible below the solid bar moisture barrier 110, and the patterning assist lines are arranged within the footprint of this topmost part of the solid bar, which is the widest part.

FIG. 3B illustrates a front view 300B of the TSV and moisture barrier showing the cut for the top level cross-section, consistent with an illustrative embodiment. Although the TSV 105 solid bar moisture barrier 110 is shown, along with the patterning assist lines having different pitches at different vertical levels the cross section is made at the top level 305 below the top of the TSV 105, which is why no patterning assist lines are visible in FIG. 3A.

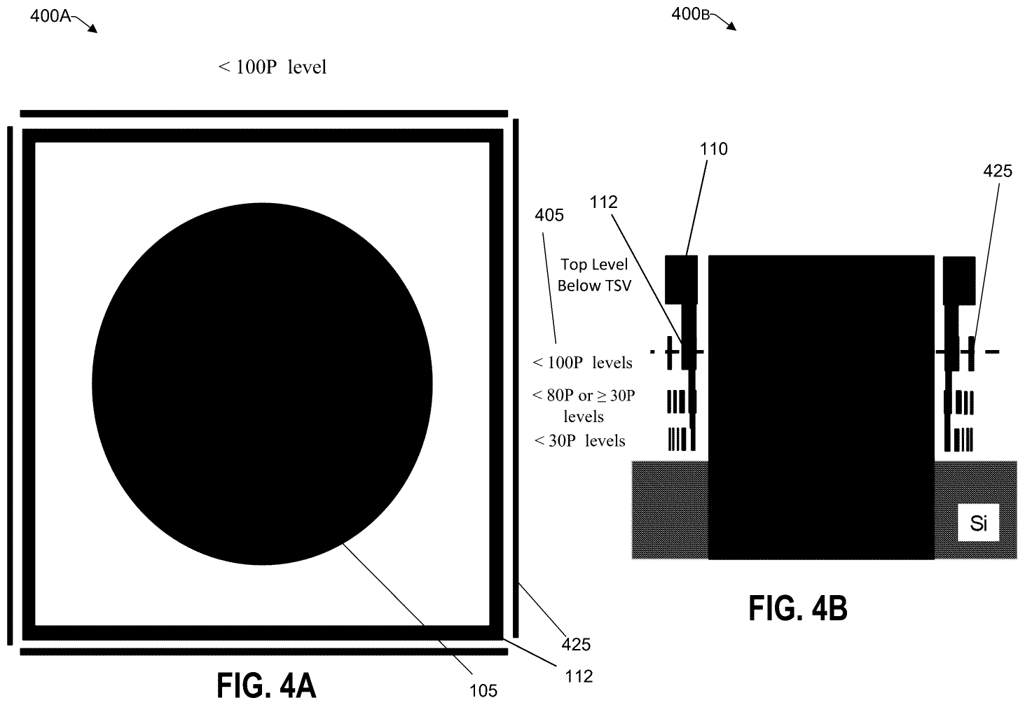

FIG. 4A illustrates a cross-sectional view 400A from an <100P (i.e. 100 micron pitch) level portion of the TSV and moisture barrier, consistent with an illustrated embodiment. It is to be understood that the <100P level is selected for illustrative purposes, and all three of the levels shown do not limit the practice of the moisture barrier according to the embodiments of the present disclosure. With the slice of the cross-section taken at the <100P level 405 (FIG. 4B), there is shown the TSV 105, a first tapered portion 112 of the solid bar moisture barrier 110, and the patterning assist line 425.

FIG. 4B illustrates a front view 400B of the TSV and moisture barrier showing the cut for the pitch <100 nm or pitch ≥80 nm level cross-section, consistent with an illustrative embodiment. The first tapered portion 112 of the solid bar moisture barrier 110 is shown at the pitch <100P level 405.

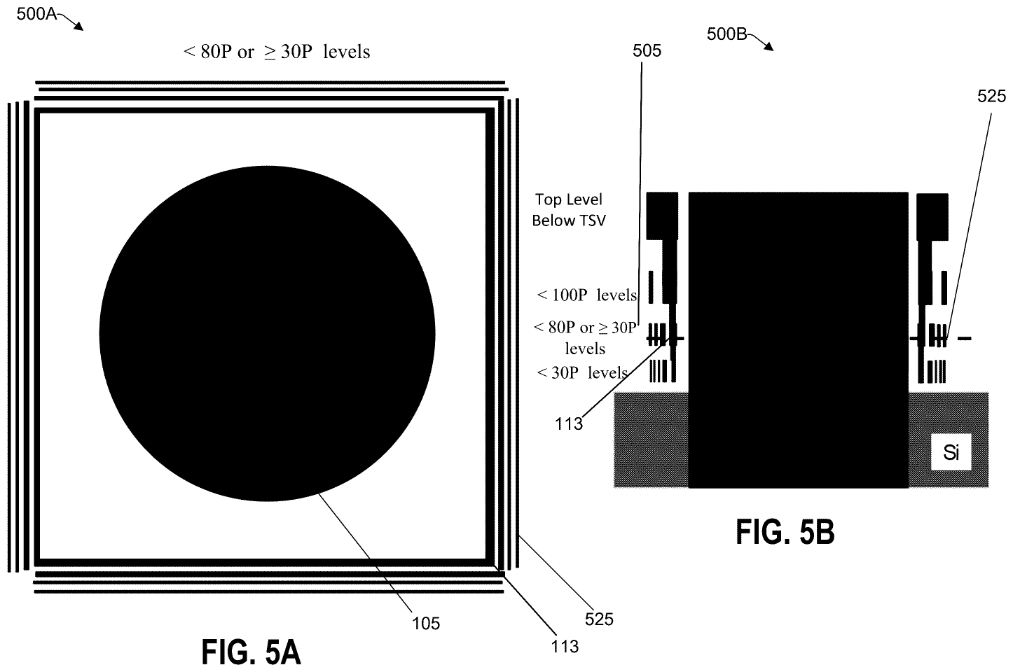

FIG. 5A illustrates a cross-sectional view 500A from a width pitch <80 nm or pitch ≥30 nm level portion of the TSV and moisture barrier, consistent with an illustrative embodiment. With the slice of the cross-section taken at the width pitch <80 nm or pitch ≥30 nm level 505 (FIG. 5B), there is shown the TSV 105, a second tapered portion 113 of the solid bar moisture barrier 110, and the patterning assist lines 525.

FIG. 5B illustrates a front view 500B of the TSV and moisture barrier showing the cut for the width pitch <80 nm or pitch ≥30 nm level 505 cross-section, consistent with an illustrative embodiment. The second tapered portion 113 of the solid bar moisture barrier 110 is shown at the pitch <80 nm or pitch ≥30 nm level 505. The patterning assist lines 525 are shown.

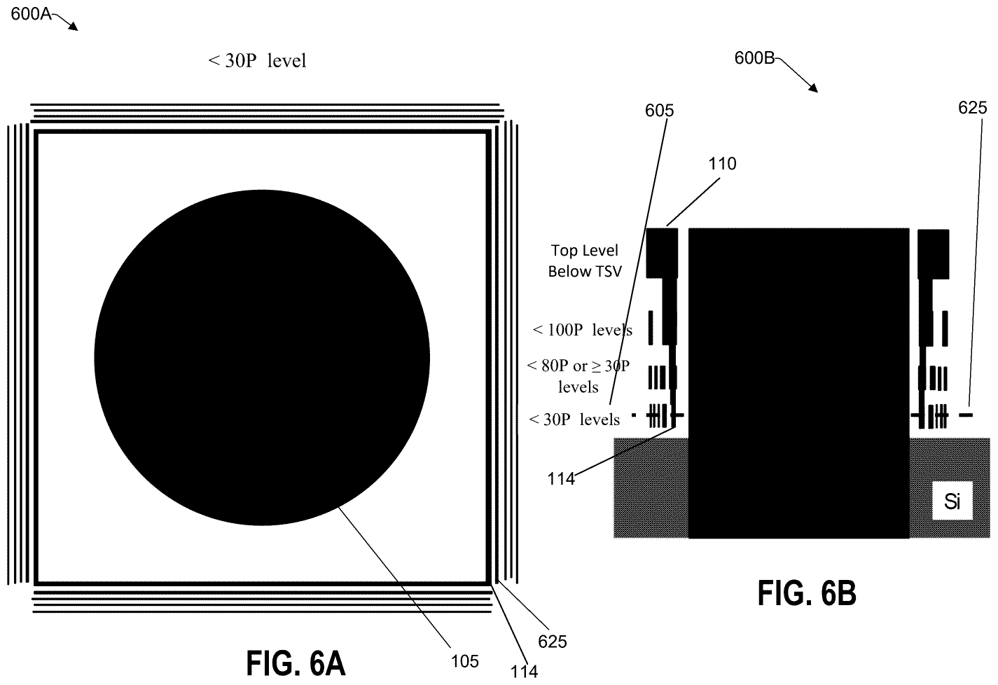

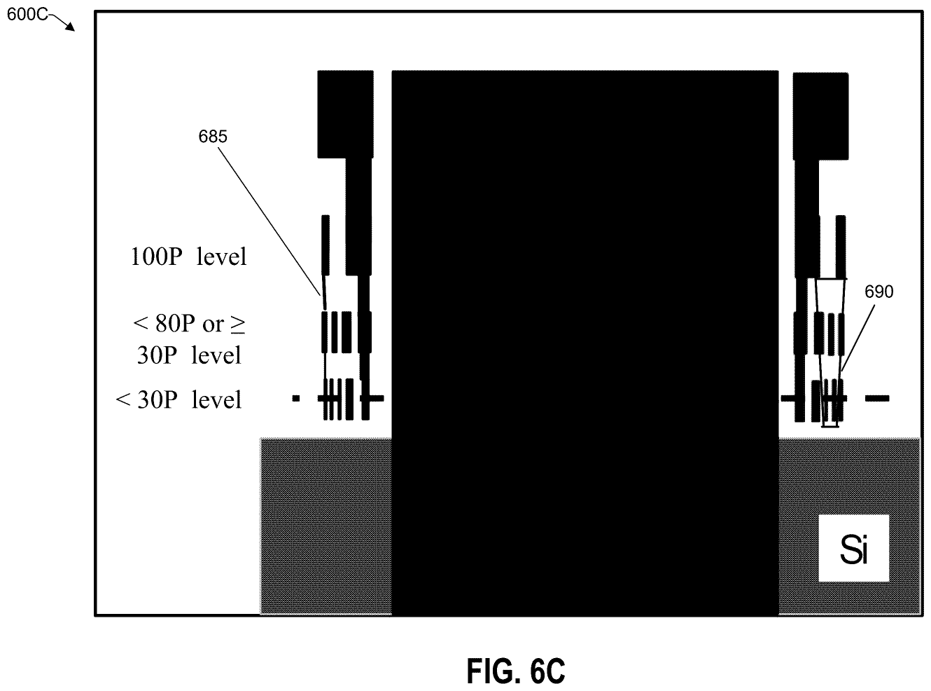

FIG. 6A illustrates a cross-sectional view 600A of the TSV and moisture barrier at the <30 nm P level portion, consistent with an illustrative embodiment. It is to be understood the <30 nm P level is shown for illustrative purposes, as it represents the third smallest pitch in a three-vertical tier semiconductor structure. It is to be understood that there may be more vertical tiers than shown or fewer. With the slice of the cross-section taken at the <30 nm P level 605 (FIG. 6B), there is shown the TSV 105, a third tapered portion 114 of the solid bar moisture barrier 110, and the patterning assist lines 625. Compared with FIGS. 4A and 5A, it can be seen there are more patterning assist lines shown in FIG. 6A because the third tapered portion is smaller than the first or second tapered portions.

FIG. 6B is a front view 600B of the TSV and moisture barrier showing the cut for a <30 nm P level cross-section, consistent with an illustrative embodiment. The third tapered portion 114 of the solid bar moisture barrier 110 is shown at the <30 nm P level 605. The patterning assist lines 625 are shown.

FIG. 6C is a front view 600C of the TSV and moisture barrier including a second TSV in the patterning assist lines area, and connections between pitch patterning assist lines of different pitches along different vertical levels, consistent with an illustrative embodiment. The second TSV 690 is connected between three all three rows patterning assist lines (e.g. >100P, with pitch <100 nm or pitch ≥80 nm, with pitch <80 nm or pitch ≥30 nm, <30P). However, the TSV may be connected between only two rows of patterning assist lines. There may also optionally be connections 685 between the different rows of patterning assist lines. For example, there may be just a connection 685 between the pitch <100 nm or pitch ≥80 nm level and the 30P level, or just a connection between the with pitch <80 nm or pitch ≥30 nm level and the <30P level, or all three levels as shown in FIG. 6C.

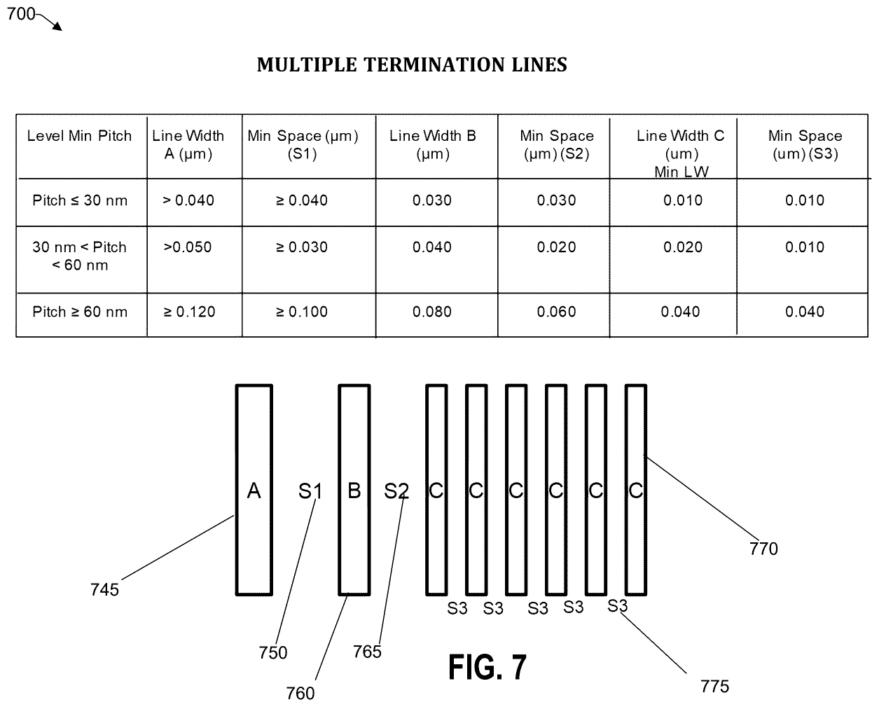

FIG. 7 shows reference data and spacing of patterning assist lines, consistent with an illustrative embodiment. Table 700 shows multiple termination lines having line widths, and minimum space at spaces S1 750, S2 765, and S3 775 for the patterning assist line widths A 745, B 760, and C 770. It is shown that the line widths and the spaces patterning assist are arranged in a type of gradient configuration. The arrangement helps to construct the patterning assist lines and helps to create a more robust line for line A 745 (which is closest to the tapered portion of the solid bar moisture barrier 110 solid bar shown in FIG. 1).

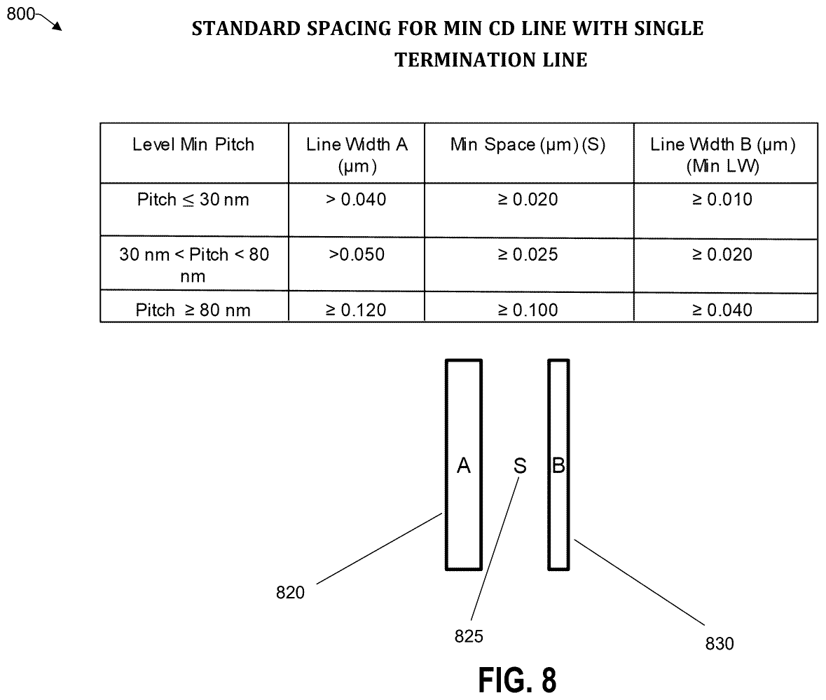

FIG. 8 shows reference data and spacing of patterning assist lines, consistent with an illustrative embodiment. Table 800 shows the line width and spacing for a single termination line, which may be used with the thickest line (e.g. the pitch <100 nm or pitch ≥80 nm level). Here the line widths are identified as A 820 and B 830, with a minimum space of S 825 in between.

It is to be understood that although the present disclosure shows illustrative embodiments with single-walled moisture barriers there may be double-walled, triple-walled moisture barriers, or more than triple-walled structures provided. The benefits will be the same if there are more walls, with a reduced possibility of moisture ingress with each additional wall.

### Example Process

With the foregoing overview of the example architecture, it may be helpful now to consider a high-level discussion of an example process. To that end, FIG. is a flowchart 900 illustrating a method of constructing a moisture barrier for a semiconductor structure, consistent with an illustrated embodiment.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

The method begins with arranging the solid bar in a semiconductor structure, typically before inserting the TSV (operation 902). The purpose of the TSV is to provide more efficient connections between layers on a semiconductor structure, mainly on the BEOL. The solid bar is inserted to surround an area where the TSV will be inserted. As shown in FIG. 1, and FIGS. 3A through 6C, the solid bar moisture barrier 110 is tapered downward, with the widest part at the topmost portion.

Patterning assist lines are provided underneath the solid bar within the footprint of the widest part of the solid bar (operation 904). The patterning assist lines are arranged a the tapered portions of the solid bar underneath the topmost portion. By arranging the patterning assist lines within the footprint of the solid bar, the typically keep-out zone is eliminated or reduced, while the performance of the TSV is enhanced, and at the same time, moisture protection is provided that prevents device failure.

The patterning assist lines are varied in pitch according to their vertical level (operation 906). Typically the pitch is larger near the topmost part of the solid bar, and the pitch decreases toward the portion of the bar closer to the substrate (including but not limited to the SI substrate shown) in FIG. 1. Although some of the drawings show pitches of 100 nm, 80 nm, and 30 nm, these pitch sizes have been provided for illustrative purposes. There is no requirement that the pitch size, or the difference between the pitches is a certain ratio or range based on the pitch size in the drawings. For example, in a three vertical tier (e.g. 3 levels) patterning assist line structure, the first tier is closest to the topmost portion of the solid bar is largest, the second vertical tier is smaller than the pitch size of the first tier, and the third tier has the smallest pitch size of the three vertical tiers. There can more more than three tiers, or less.

Across each particular vertical tier, the thickness of the patterning assist lines increases as the distance from the solid bar decreases (operation 908) FIGS. 7 and 8 show that the line A is the thickest, followed by B and C. Thus, both the thickness of the lines and the space between the lines (shown as S1, S2, S3) decrease away from the Solid bar (see FIGS. 3B and 4B, where the thickest line is closest to the solid bar). Typically the outer lines are made first and they are thinner and as the lines approach the solid bar they are thick, such as shown in FIGS. 3B and 4B.

At least one TSV is made in an area of the semiconductor structure surrounded by the solid bar (operation 910). The provision of the TSV can introduce moisture thus it may be preferable to first construct the moisture barrier and then the TSV, but the present disclosure is not limited to any particular order in this regard.

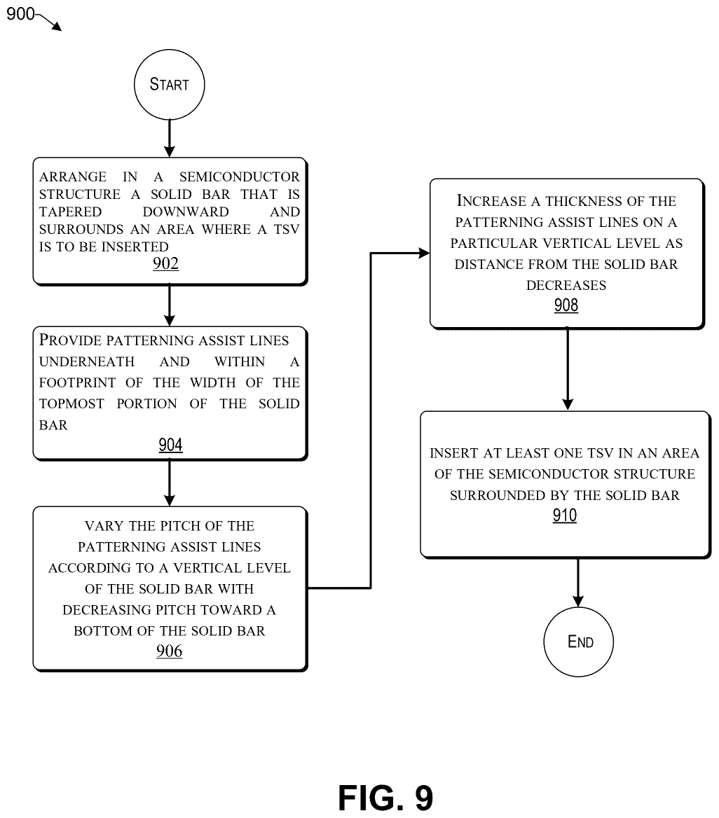

While the method shown in FIG. 9 ends after operation 910, it is understood that additional operations such as connecting patterning lines from various tiers (FIG. 6C connections 685) and or adding additional TSVs (FIG. 6C element 690) may be performed.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to better explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, operations, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits, and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any such actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A moisture barrier for a semiconductor structure, the moisture barrier comprising:
a solid bar that is tapered from an uppermost portion to a lowermost portion and extends along a length of the moisture barrier to form a collar that surrounds a designated area of the semiconductor structure configured to arrange at least one through silicon via (TSV); and
a plurality of patterning assist lines that are arranged at different vertical levels adjacent the solid bar within a footprint having a width defined by a topmost level of the solid bar.

2. The moisture barrier according to claim 1, wherein:
the solid bar is tapered so that the width of the uppermost portion is a widest portion; and
the patterning assist lines each have different pitches at the different vertical levels of tapering of the solid bar.

3. The moisture barrier according to claim 1, wherein the patterning assist lines have a same pitch at a particular vertical level of the different vertical levels of tapering of the solid bar.

4. The moisture barrier according to claim 1, wherein:
the at least one TSV is arranged in the designated area of the semiconductor device structure; and
the moisture barrier extends at least along a Back End of Line (BEOL) of the semiconductor device.

5. The moisture barrier according to claim 4, wherein a thickness of the patterning assist lines on a particular vertical level of tapering of the solid bar increases as a distance from the at least one TSV decreases.

6. The moisture barrier according to claim 1, further comprising at least three different vertical levels of tapering of the solid bar at which the patterning assist lines are arranged within the footprint of the solid bar.

7. The moisture barrier according to claim 6, wherein:
a first pitch of the patterning assist lines is largest at a topmost first vertical level of the three different vertical levels of tapering of the solid bar;
a second pitch of the patterning assist lines at a second vertical level below the topmost first vertical level that is smaller than the first pitch; and
a third pitch of the patterning assist lines at a third vertical level below the second vertical level that is smallest.

8. The moisture barrier according to claim 7, wherein the patterning assist lines of the topmost first vertical level are connected to the patterning assist lines of the second vertical level.

9. The moisture barrier according to claim 7, wherein the patterning assist lines of a second level are connected to the patterning assist lines of the third vertical level.

10. The moisture barrier according to claim 7, wherein:
the patterning assist lines of the topmost first vertical level are connected to the patterning assist lines of the second vertical level; and
the patterning assist lines of the second vertical level are connected to the patterning assist lines of the third vertical level.

11. The moisture barrier according to claim 7, further comprising at least a second TSV arranged between the different vertical levels of the patterning assist lines.

12. A method of constructing a moisture barrier for a semiconductor structure, the method comprising:
arranging, in a semiconductor structure, a solid bar that is tapered from an uppermost portion to a lowermost portion and surrounds a designated area of the semiconductor structure configured to arrange at least one through silicon via (TSV); and
forming a plurality of patterning assist lines that are arranged at different vertical levels of tapering of the solid bar within a footprint of the solid bar having a width defined by a topmost level.

13. The method according to claim 12 further comprising providing the patterning assist lines with different pitches at the different vertical levels of tapering of the solid bar.

14. The method according to claim 12, further comprising providing the patterning assist lines to have a same size pitch at a particular vertical level of the different vertical levels of tapering of the solid bar.

15. The method according to claim 12, further comprising arranging the at least one TSV in the designated area of the semiconductor structure, and extending the moisture barrier at least along a Back End of Line (BEOL) of the semiconductor structure.

16. The method according to claim 15, wherein a thickness of the patterning assist lines on a particular vertical level increases as a distance from the solid bar decreases.

17. The method according to claim 12, further comprising providing the patterning assist lines of at least three different vertical levels within the footprint of the solid bar at which the patterning assist lines are arranged.

18. The method according to claim 17, wherein the providing of the patterning assist lines includes a first pitch that is largest at a topmost first vertical level of the three different vertical levels, a second pitch of the patterning assist lines at a second vertical level below the topmost first vertical level that is smaller than the first pitch, and a third pitch of the patterning assist lines at a third vertical level below the second vertical level that is smallest.

19. The method according to claim 17, wherein the method further comprises connecting the patterning assist lines of at least some of the at least three different vertical levels.

20. The method according to claim 17, wherein the method further comprises providing at least a second TSV that is arranged between the different vertical levels of the patterning assist lines.
